(19) United States
(12) Patent Application Publication
(10) Pub. No.: US 2026/0371578 A1
(43) Pub. Date: Nov. 19, 2026

(54) SEMICONDUCTOR DEVICE AND METHOD OF FABRICATING THE SAME

(71) Applicant: Fujian Jinhua Integrated Circuit Co., Ltd, Quanzhou City (CN)

(72) Inventors: Yiwei Qiu, Quanzhou City (CN); Janbo Zhang, Quanzhou City (CN); Tian Fu, Quanzhou City (CN); Xiuhua Ma, Quanzhou City (CN); Weizhi Huang, Quanzhou City (CN)

(73) Assignee: Fujian Jinhua Integrated Circuit Co., Ltd, Quanzhou City (CN)

(21) Appl. No.: 19/674,166

(22) Filed: May 12, 2026

(30) Foreign Application Priority Data
May 16, 2025 (CN) 202510637528.8

(51) Int. Cl. H10B 12/00

(52) U.S. Cl. CPC H10B 12/50; H10B 12/09; H10B 12/315

(57) ABSTRACT

A semiconductor device and a fabricating thereof includes a substrate, a first plug, a conductive pad, and a metal oxide layer. The first plug is disposed on the substrate. The conductive pad is disposed on the first plug, to physically contacts the first plug. The covering layer includes a first portion on a top surface of the conductive pad and a second portion on a sidewall of the conductive. The metal oxide layer is disposed on the second portion of the covering layer, wherein a topmost point of the metal oxide layer is lower than a topmost point of the covering layer, and a lowest point of the metal oxide layer is higher than a lowest point of the first plug.

### CROSS REFERENCE TO RELATED APPLICATION

This application claims the benefit of Chinese Patent Application No. 202510637528.8 filed on May. 16, 2025, which is incorporated herein by reference.

### BACKGROUND OF THE INVENTION

### 1. Field of the Invention

The present invention generally relates to a semiconductor technique, and more particularly, to a semiconductor device and a method of fabricating the same.

### 2. Description of the Prior Art

With the trend of miniaturization of various electronic products, the design of semiconductor devices must also meet the requirements of high integration and high density. For dynamic random access memories (DRAMs) having recessed gate structures, current leakage of capacitor structures can be reduced due to longer carrier channel length in the same semiconductor substrate. Therefore, under the current mainstream of development trend, they have gradually replaced the DRAMs having only planar gate structures. In general, a DRAM with a recessed gate structure includes a huge number of memory cells, which form an array region for storing data. Each of the memory cells includes a transistor component and a capacitor component connected in series to receive voltage signals from bit lines and word lines. To meet the demands on features of products, it is still necessary to keep raising the intensity of the memory cells in the array region. As a result, the manufacturing process and the design would become more and more critical, and the complexity would be higher and higher. Therefore, the prior art techniques or the conventional structures need to be further improved to effectively improve the performance and reliability of related memory devices.

### SUMMARY OF THE INVENTION

An object of the present invention is to provide a semiconductor device, in which a metal oxide layer is additionally disposed on a sidewall of a conductive pad, with a topmost point of the metal oxide layer being higher than the a topmost point of the conductive pad, and with a lowest point of the metal oxide layer being higher than a lowest point of the conductive pad. Through arranging the metal oxide layer in the semiconductor device, the possible structural defects occurred at a peripheral region of the semiconductor device will be dramatically improved, and the short circuit issue between the conductive pad and metal interconnection disposed adjacent thereto will also be avoided thereby.

An object of the present invention is to provide a fabricating method of a semiconductor device, where a metal oxide layer is additionally formed on a sidewall of a conductive pad, without introducing additional processes. The metal oxide layer formed accordingly includes a topmost point of the metal oxide layer being higher than a topmost point of the conductive pad, and a lowest point of the metal oxide layer being higher than a lowest point of the conductive pad. Through forming the metal oxide layer, the possible structural defects occurred at a peripheral region of the semiconductor device will be dramatically improved, and the short circuit issue between the conductive pad and metal interconnection disposed adjacent thereto will also be avoided thereby.

In order to achieve the above objects, an embodiment of the present invention provides a semiconductor device, which includes a substrate, a first plug, a conductive pad, and a metal oxide layer. The first plug is disposed on the substrate. The conductive pad is disposed on the first plug, to physically contact the first plug. The covering layer includes a first portion disposed on a top surface of the conductive pad and a second portion disposed on a sidewall of the conductive pad. The metal oxide layer is disposed on the second portion of the covering layer, wherein a topmost point of the metal oxide layer is lower than a topmost point of the covering layer, and a lowest point of the metal oxide layer is higher than a lowest point of the first plug.

In order to achieve the above objects, an embodiment of the present invention provides a fabricating method of a semiconductor device, including the following steps. A substrate is provided. A first plug is formed on the substrate. A conductive pad is formed on the first plug, and the conductive pad is in physical contact with the first plug. A covering layer is formed on the conductive pad, and includes a first portion disposed on a top surface of the conductive pad and a second portion disposed on a sidewall of the conductive. A metal oxide layer is formed on the second portion of the covering layer, wherein a topmost point of the metal oxide layer is lower than a topmost point of the covering layer, and a lowest point of the metal oxide layer is higher than a lowest point of the first plug.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIGS. 1 and FIG. 2 are schematic diagrams illustrating a semiconductor device according to a first embodiment of the present application, wherein:

FIG. 1 is a cross-sectional view of a semiconductor device; and

FIG. 2 is a partial enlarged diagram of FIG. 1.

FIGS. 3 - FIG. 8 are schematic diagrams illustrating a method of fabricating a semiconductor device according to a preferred embodiment of the present invention, wherein:

FIG. 3 is a cross-sectional view illustrating a semiconductor device after forming a supporting layer structure;

FIG. 4 is a cross-sectional view illustrating a semiconductor device after forming a bottom electrode material layer;

FIG. 5 is a cross-sectional view illustrating a semiconductor device after forming bottom electrode;

FIG. 6 is a cross-sectional view illustrating a semiconductor device after partially removing the supporting material layer structure;

FIG. 7 is a cross-sectional view illustrating a semiconductor device after forming a supporting layer structure;

FIG. 8 is a cross-sectional view illustrating a semiconductor device after forming a metal oxide material layer; and

FIG. 9 is a cross-sectional view illustrating a semiconductor device after forming a capacitor structure.

FIG. 10 is a schematic diagram illustrating a semiconductor device according to a second embodiment of the present application.

FIG. 11 is a schematic diagram illustrating a semiconductor device according to a third embodiment of the present application.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

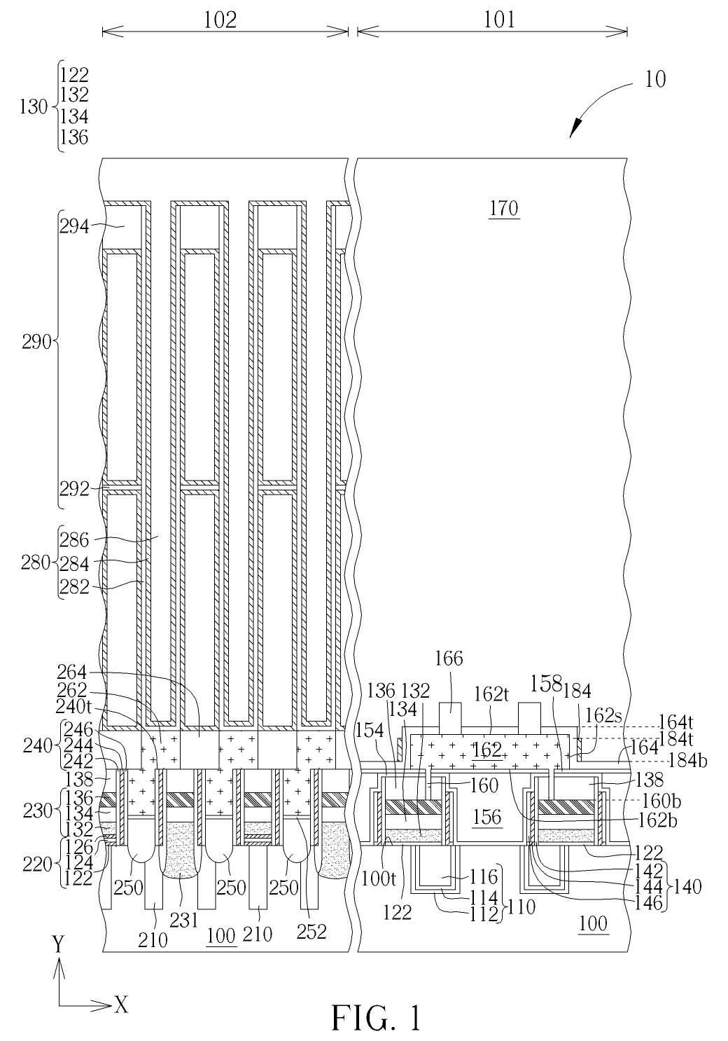

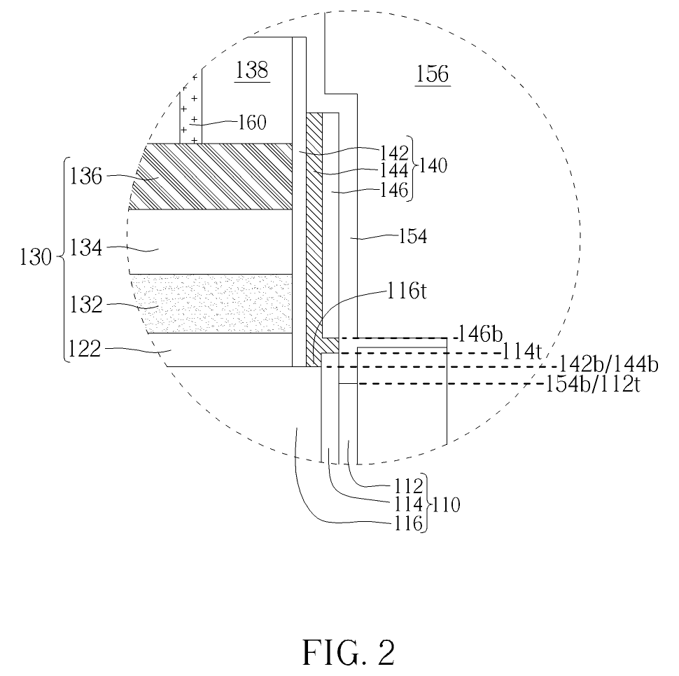

Please refer to FIGS. 1 - FIG. 2, which schematically illustrate a semiconductor device 10 according to a first embodiment of the present application. As shown in FIG. 1, the semiconductor device 10 includes a substrate 100, at least one first plug 160 and at least one contact pad 162 disposed on the substrate 100, and a covering layer 164 and a metal oxide layer 184 stacked in sequence on the at least conductive pad 162. The substrate 100 for example includes a silicon substrate, a silicon-containing substrate, an epitaxial silicon substrate, a silicon-on-insulator (SOI) substrate, or a substrate formed of any other suitable material. In one embodiment, the substrate 100 further includes a first region 101, for example serving as a peripheral region of the semiconductor device 10, where the component integration level is relatively low, and a second region 102, for example serving as a cell region of the semiconductor device 10, where the component integration level is relatively high. The first region 101 and the second region 102 may be disposed adjacent to each other, as shown in FIG. 1, but not limited thereto. Furthermore, at least one shallow trench isolation (STI) 110, 120 are respectively disposed within the first region 101 and the second region 102 of the substrate 100, and a plurality of active areas (AA, not shown in the drawings) is defined thereby in the substrate 100.

The at least one conductive pad 162 is disposed on the at least one plug 160, to physically contact the at least one plug 160, and the covering layer 164 partially overlays a top surface 162t and partially overlays a sidewalls 162s of the at least one conductive pad 162 in a conformal manner. It is noted that, the metal oxide layer 184 is disposed on a portion of the covering layer 164 overlaying the sidewall 162s of the at least one conductive pad 162, with a topmost point 184t of the metal oxide layer 184 being lower than a topmost point 164t of the covering layer 164, and the top surface 162t of the at least one conductive pad 162, and with a lowest point 184b of the metal oxide layer 184 being higher than a lowest point 160b of the at least one first plug 160, and a bottom surface 162b of the at least one conductive pad 162. In other words, the arrangement of the metal oxide layer 184 will dramatically improve the structural defect possibly occurred on components within the first region 101 of the semiconductor device 10, without additionally increasing the entire height of components within the first region 101 of the semiconductor device 10, so that, the short circuit issues between the at least one conductive pad 162 and metal interconnections adjacent thereto will be successfully avoided thereby. In this way, the semiconductor device 10 in the present embodiment is allowable to gain better structural reliability and functions.

The semiconductor device 10 further includes at least one gate structure 130, a gate spacer structure 140, an etching stop layer 154, dielectric layers 156, 158 and at least one second plug 166 all disposed within the first region 101, and the metal oxide layer 184 is disposed right above the at least one gate structure 130. Precisely speaking, the at least one gate structure 130 is partially disposed on the at least one shallow trench isolation 110, and includes an oxide layer 122, a semiconductor layer 132, a barrier layer 134 and a metal layer 136 stacked in sequence on a surface 100t of the substrate 100, in a vertical direction Y, with the oxide layer 122 being served as a gate oxide layer of the at least one gate structure 130. Also, a cap layer 138 is additionally disposed on the metal layer 136 of the at least one gate structure 130. In one embodiment, the semiconductor layer 132 includes, for example, a semiconductor material such as doped polysilicon or doped amorphous silicon, the barrier layer 134 includes, for example, a conductive barrier material such as titanium and/or titanium nitride (TiN), tantalum (Ta) and/or tantalum oxide, the metal layer 136 includes, for example, copper, aluminum, tungsten or other suitable conductive materials with low resistivity, and the cap layer 138 includes, for example, an insulating material such as silicon oxide, silicon nitride or silicon oxynitride, but not limited thereto.

It is noted that, a top surface (namely the top surface of the metal layer 136) of the at least one gate structure 130 physically contacts the lowest point 160b of the at least one first plug 160, and the at least one second plug 166 is disposed on the at least one conductive pad 162, so that, the at least one second plug 166 is electrically connected to the at least one conductive pad 162, the at least one first plug 160 disposed underneath, and the at least one gate structure 130. The at least one second plug 166, the at least one first plug 160 and the at least one conductive pad 162 comprise a conductive material like aluminum, copper, titanium or tungsten, and the at least one first plug 160 and the at least one conductive pad 162 are preferably monolithic, but not limited thereto. Accordingly, the at least one second plug 166 is allowable to serve as a first layer metal interconnection of the semiconductor device 10, and the at least one gate structure 130 disposed within the first region 101 will be electrically connected to other conductive structures subsequently disposed on the semiconductor device 10 through the at least one second plug 166.

The gate spacer structure 140 is disposed on a sidewall of the at least one gate structure 130, to partially disposed on the at least one shallow trench isolation 110, and the etching stop layer 154, and the dielectric layers 156, 158 are stacked in sequence on the substrate 100, with the etching stop layer 154 overlaying the gate spacer structure 140 and the at least one gate structure 130 in a conformal manner, and with the dielectric layers 156, 158 entirely overlaying the etching stop layer 154, as shown in FIGS. 1 and FIG. 2. The gate spacer structure 140 includes a first spacer 142, a second spacer 144 and a third spacer 146 sequentially arranged on the sidewall of the at least one gate structure 130 in a horizontal direction X, with the first spacer 142 and the third spacer 146 respectively including a cross-sectional structure of I-shape, and with the second spacer 144 including a cross-sectional structure of L-shape. The third spacer 146 is disposed on the second spacer 144 in the vertical direction Y, so that, a bottom surface 146b of the third spacer 146 is higher than bottom surfaces 142b, 144b of the first spacer 142 and the second spacer 144. The top surfaces of the second spacer 144 and the third spacer 146 are coplanar with each other, and lower than the top surfaces of the first spacer 142 and the cap layer 138. In one embodiment, the first spacer 142 and the third spacer 146 for example includes the same insulating material like silicon nitride or silicon carbonitride, and the second spacer 144 for example includes an insulating material being different from that of the first spacer 142 and the third spacer 146, such as silicon oxide or silicon oxynitride. The etching stop layer 154 and the dielectric layer 156 are preferably include different insulating materials like silicon nitride and silicon oxide, but not limited thereto.

On the other hand, the at least one shallow trench 110 includes a first insulating layer 112, a second insulating layer 114 and a third insulating layer 116 disposed in sequence in the horizontal direction X, with all of the first insulating layer 112, the second insulating layer 114 and the third insulating layer 116 being lower than the surface 100t of the substrate 100, as shown in FIG. 2. The top surface 114t of the second insulating layer 114 is higher than top surfaces 112t, 116t of the first insulating layer 112 and the third insulating layer 116, to physically contact the second spacer 144 of the gate spacer structure 140, and the top surface 116t of the third insulating layer 116 physically contacts the first spacer 142 and the second spacer 144 of the gate spacer structure 140 at the same time. That is, the second spacer 144 of the gate spacer structure 140 is partially disposed on the third insulating layer 116, and partially disposed on the second insulating layer, to simultaneously contact the sidewall and the top surface 114t of the second insulating layer 114, and the top surface 116t of the third insulating layer 116. The portion of the etching stop layer 154 overlaying the gate spacer structure 140 is partially extended into the second insulating layer 114 and the first insulating layer 112 of the at least one shallow trench isolation 110, such that, the lowest point 154b of the etching stop layer 154 is lower than the surface 100t of the substrate 100. Accordingly, the etching stop layer 154 physically contact the sidewall of the second insulating layer 114 and the top surface 112t of the first insulating layer 112 of the at least one shallow trench isolation 110 at the same time, and the at least one gate structure 130 disposed within the first region 101 will therefore gain a stable structure as shown in FIG. 2, but not limited thereto.

In one preferable embodiment, the semiconductor device 10 for example includes two shallow trench isolations 110 within the first region 101, two gate structures 130 cross two shallow trench isolations 110 respectively, two first plugs 160 contacting the top surfaces of the two gate structures 130 respectively, and two second plugs 166 disposed on the at least one conductive pads 162 respectively. Precisely speaking, the at least one conductive pad 162 simultaneously contacts the two first plugs 160, and also simultaneously contacts the two second plugs 166, and an insulating layer 170 entirely overlays the second plugs 166 and the at least one conductive pad 162, as shown in FIG. 1. The two first plugs 160 are respectively disposed between the at least one contact pad 162 and the two gate structures 130, so that the two gate structures 130 may be electrically connected to other conductive structures through the two first plugs 160 and the two second plugs 166, respectively. It is noted that two opposite sidewalls of the at least one contact pad 162 are respectively disposed over the two gate structures 130, such that, the metal oxide layer 184 is simultaneously disposed on the covering layer 164 overlaying the two opposite sidewalls, being right above the two gate structures 130, as shown in FIG. 1. In this way, the short circuit issues between each gate structure 130 and metal interconnections adjacent thereto will be successfully avoided thereby.

Further in view of FIG. 1, the semiconductor device 10 further includes a plurality of bit lines 230, a plurality of plugs 250, a plurality of conductive pads 262 and a capacitor structure 280 disposed within the second region 102. The bit lines 230 and the plugs 250 are alternately arranged with each other, on the substrate 100, with a bit-line spacer structure 240 being disposed between each bit line 230 and each plug 250. Each conductive pad 262 is partially disposed on each plug 250, and partially disposed on each bit line 230, so that, the portions of the conductive pads 262 disposing on the plugs 250 also be alternately arranged with the bit lines 230. Precisely speaking, the bit lines 230 are basically disposed on the dielectric layer 220, and extend into the substrate 100 through corresponding bit line contacts (BLC) 231 disposed underneath to be electrically connected to the corresponding active areas. Each of the bit lines 230 includes the semiconductor layer 132 (for example including a semiconductor material such as doped polysilicon or doped amorphous silicon), the barrier layer 134 (for example including a conductive barrier material such as titanium and/or titanium nitride, tantalum and/or tantalum oxide), the metal layer 136 (for example including a metal material with low resistivity, like copper, aluminum, tungsten) and the cap layer 138 (for example including an insulating material such as silicon oxide, silicon nitride or silicon oxynitride) stacked from bottom to top. In one embodiment, the dielectric layer 220 includes, for example, a silicon oxide layer 122, a silicon nitride layer 124 and a silicon oxide layer 126 stacked in sequence to result in an oxide-nitride-oxide (ONO) structure, but not limited thereto. the bit-line spacer structure 240 includes a first spacer 242, second spacer 244 and a third spacer 246 disposed in sequence on the sidewall of each bit line 230, in the horizontal direction X, with the first spacer 242, the second spacer 244 and the third spacer 246 having coplanar top surfaces 240t, to level with the top surface of the bit lines 230.

In one embodiment, a process of forming the dielectric layer 220 may be integrated with a process of forming the gate dielectric layer disposed within the first region 101, so that, the oxide layer 122 of the dielectric layer 220 and the gate dielectric layer of the gate structures 130 will include the same film structure and the same material. On the other hand, a process of forming the bit lines 230 may be integrated with a process of forming gate structures 130 within the first region 101, so that, the semiconductor layer 132, the barrier layer 134, the metal layer 136, and the cap layer 138 of the bit lines 230 and the semiconductor layer 132, the barrier layer 134, the metal layer 136, and the cap layer 138 of the gate structures 130 will also include the same film structure and the same material, respectively. In another embodiment, a process of forming the bit-line spacer structure 240 may also be integrated with a process of forming the gate spacer structure 140, so that, the first spacer 242, the second spacer 244 and the third spacer 246 of the bit-line spacer structure 240 and the first spacer 142, the second spacer 144 and the third spacer 146 of the gate spacer structure will include the same film structure and the same material, respectively.

The plugs 250 for example include, for example, an epitaxial material such as silicon, silicon phosphorus, silicon germanium, or germanium, to serve as storage node contacts (SN contact) of the semiconductor device 10, for physically contacting the corresponding active areas, and the conductive pads 262 disposed on the plugs 250 are served as storage node pads (SN pads) of the semiconductor device 10. Accordingly, the capacitor structure 280 disposed on the conductive pads 262 is electrically connected to the corresponding active areas through the storage node pads and the storage node contacts. In one embodiment, a metal silicide layer 252 is further disposed between each conductive pad 262 and each plugs 250, and which includes, for example, a metal silicide material like cobalt disilicide (CoSi₂), titanium disilicide (TiSi₂) or nickel silicide (Ni₂Si), but not limited thereto. Furthermore, in another embodiment, a process of forming the conductive pads 262 may be integrated with a process of forming the at least one conductive pad 162 and the first plugs 160 within the first region 101, to that, the conductive pads 262, the at least one conductive pad 162 and the first plugs 160 will include the same film structure and the same material, for example each including a barrier layer (not shown in the drawings, for example including a conductive barrier material like titanium/titanium nitride, tantalum/tantalum nitride) and a metal layer (not shown in the drawings, for example including a low-resistant metal material like copper, aluminum, titanium or tungsten) stacked in sequence, but not limited thereto.

Furthermore, the capacitor structure 280 includes a plurality of bottom electrodes 282, a capacitor dielectric layer 284 and top electrode layers 286 disposed in sequence, to form a plurality of vertically extending capacitors, serving as storage nodes (SN) of the semiconductor device 10. The middle portion and the upper portion of each capacitor respectively contact a first supporting layer 292 and a second supporting layer 294 of a supporting structure 290, with the supporting structure 290 providing stable support for the structure of the capacitor structure 280. In one embodiment, the bottom electrodes 282 include, for example, titanium nitride. The top electrode layers 286 include, for example, a composite structure of titanium nitride and silicon germanium. The capacitor dielectric layer 284 includes, for example, a high dielectric constant dielectric material selected from a group of metal oxides, such as hafnium oxide (HfO₂), hafnium silicon oxide (HfSiO₄), hafnium silicon oxynitride (HfSiON), zinc oxide (ZrO₂), titanium oxide (TiO₂) and zirconia-alumina-zirconia (ZAZ), and preferably includes zirconia-alumina-zirconia, but not limited thereto. In a preferred embodiment, a process of forming the capacitor dielectric layer 284 may be integrated with a process of forming the metal oxide layer 184 within in the first region 101. For example, when the capacitor dielectric layer 284 is formed, the metal oxide layer 184 is simultaneously formed within the first region 101, so that the capacitor dielectric layer 284 and the metal oxide layer 184 may include the same film structure and the same dielectric material.

With these arrangements, each capacitor and a transistor component (not shown in the drawings) within in the second region 102 of the substrate 100 can form a minimum memory cell to receive voltage information from the bit lines 230 and the word lines (not shown in the drawings), so that the semiconductor device 10 in the present embodiment will form a dynamic random access memory (DRAM) device to achieve enhanced operating performance. According to the present embodiment, the metal oxide layer 184 is additionally disposed on the covering layer 164 overlaying the sidewall 162s of the at least one conductive pad 162 within the peripheral region, with the topmost point 184t of the metal oxide layer 184 being lower than the topmost point 164t of the covering layer 164, and the top surface 162t of the at least one conductive pad 162, and with the lowest point 184b of the metal oxide layer 184 being higher than the lowest point 160b of the first plug 160, and the bottom surface 162b of the at least one conductive pad 162. Through arranging the metal oxide layer 184, the structural defects possibly occurred on components within the peripheral region of the semiconductor device 10 are dramatically improved, without additionally increasing the entire height of components within the peripheral region of the semiconductor device 10, and the short circuit issues between the at least one conductive pad 162 and metal interconnections adjacent thereto will be successfully avoided thereby. In this way, the semiconductor device 10 in the present embodiment is allowable to gain better structural reliability and functions.

In order to meet the practical product requirements, the semiconductor device 10 in the present invention is not limited to the aforementioned embodiment, and may further include other examples. To make people skilled in the arts easily understand the semiconductor device 10 according to the present invention, a manufacturing process of the semiconductor device 10 according to the present application will be further described hereinafter.

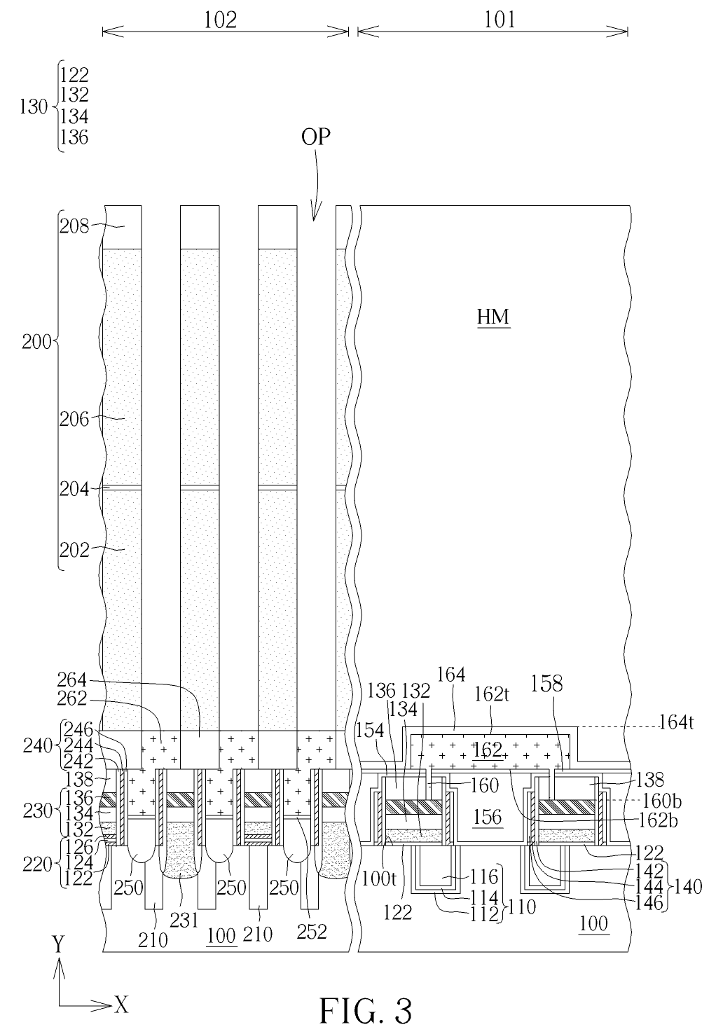

Please refer to FIGS. 3 - 9, which are schematic diagrams illustrating a process of forming the semiconductor device 10 according to a preferred embodiment of the present application. First, as shown in FIG. 3, a substrate 100 is provided, and shallow trench isolations 110, 210 are respectively formed in a first region 101 and a second region 102 of the substrate 100, to define active areas in the first region 101 and the second region 102. In one embodiment, the formation of the shallow trench isolations 110, 210 is accomplished by performing an etching process, to form a plurality of trenches (not shown in the drawings) in the substrate 100, and then filling at least one insulating material like silicon oxide or silicon nitride in the trenches, but not limited thereto. Next, a silicon oxide layer 122 is formed on the substrate 100, within the first region 101, and a dielectric layer 220 (including, for example, a silicon oxide layer 122, a silicon nitride layer 124 and a silicon oxide layer 126 stacked in sequence) is formed on the substrate 100, within the second region 102. Then, similar processes are performed to form a semiconductor layer 132, a barrier layer 134, a metal layer 136 and a cap layer 138 stacked in sequence on the silicon oxide layer 122, within in the first region 101, and also, to form bit line structures 130 (each including the semiconductor layer, the barrier layer 134, the metal layer 136, and the cap layer 138 stacked in sequence) on the dielectric layer 220, within the second region 102, with the silicon oxide layer 122, the semiconductor layer, the barrier layer 134, and the metal layer 136 formed within the first region 101 together form gate structures 130. Also, a gate spacer structure 140 and a bit-line spacer structure 240 are respectively formed on the sidewalls of the gate structures 130 within the first region 101, and the bit line structures 230.

In one embodiment, the processes of forming the silicon oxide layer 122 within the first region 101 and the dielectric layer 220 within the second region 102 include but not limited to the following steps. First, a first oxide material layer (not shown in the drawings), a nitride material layer (not shown in the drawings), and a second oxide material layer (not shown in the drawings) are formed sequentially, overlaying the first region 101 and the second region 102, and the second oxide material layer and the nitride material layer overlaying the first region 101 are removed, with the first oxide material layer remained in the first region 101 forming the silicon oxide layer 122, and the first oxide material layer, the nitride material layer and the second oxide material layer together forming the dielectric layer 220. Otherwise, in another embodiment the second oxide material layer, the nitride material layer and the first oxide material layer overlaying the first region 101 may also be all removed, and another oxide material layer is formed within the first region 101 to serve as the silicon oxide layer 122.

Furthermore, a process of forming the gate stacked structures 230 and the bit lines 130 includes, but is not limited to, the following steps. First, a plurality of openings (not shown in the drawings) penetrating through the dielectric layer 220 and partially exposing the substrate 100 are formed within the second region 102, and a semiconductor material layer (not shown in the drawings, for example including a semiconductor material like polysilicon or doped amorphous silicon) is formed both within the first region 101 and the second region 102 to fill in the openings. Next, a barrier material layer (not shown in the drawings, for example including a conductive barrier material like titanium and/or titanium nitride, tantalum and/or tantalum oxide), a metal material layer (not shown in the drawings, for example including a metal material with low resistivity, like tungsten, aluminum or copper), and a capping material layer (not shown in the drawings, for example including an insulating material like silicon oxide, silicon nitride or silicon oxynitride) sequentially are formed on the semiconductor material layer. Then, the gate structures 130 and the cap layer 138 disposed thereabove are formed within the first region 101, while the bit line structures 230 are formed within the second region 102, through a patterning process. Meanwhile, bit line contacts 231 are formed below the bit line structures 230, being monolithic with the semiconductor layer 132. On the other hand, a process of forming a gate spacer structures 140 and a bit-line spacer structure 240 includes, but is not limited to, the following steps.

First, multi-deposition processes and etching back processes are performed both within the first region 101 and the second region 102, to form a first spacer 142 (including, for example, silicon nitride or silicon carbonitride), a second spacer 144 (including, for example, silicon oxide or silicon oxynitride), and a third spacer 146 (including, for example silicon nitride or silicon carbonitride) stacked in sequence on the sidewall of each gate structure 130, and also, to form a first spacer 242, a second spacer 244 and a third spacer 246 stacked in sequence on the sidewall of each bit line structure 230, at the same time. Accordingly, the first spacer 242 of the bit-line spacer structure 240 may include the same film structure and the same material as that of the first spacer 142 of the gate spacer structures 140, the second spacer 244 of the bit-line spacer structure 240 may include the same film structure and the same material as that of the second spacer 144 of the gate spacer structures 140, and the third spacer 246 of the bit-line spacer structure 240 may include the same film structure and the same material as that of the third spacer 146 of the gate spacer structures 140, but not limited thereto.

As shown in FIG. 3, an etching stop layer 154 is formed within the first region 101, overlaying each gate structures and the gate spacer structure 140 in a conformal manner, and partially filling in the space between the first insulating layer 112 and the second insulating layer 114 of the shallow trench isolation 110. Next, at least one insulating material is formed both within the first region 101 and the second region 102, through performing a deposition process and an etching back process, and then, the at least one insulating material is partially removed by performing an etching process through a mask layer (not shown in the drawings), to form a plurality of storage contact openings (not shown in the drawings) each exposing a portion of the substrate 100, within the second region 102. Afterwards, the mask layer is completely removed. Then, a plurality of plugs 250 is formed within the storage contact openings respectively, and a metal silicide layer 252 is formed on each plug 250, through performing a metal silicidation process. On the other hand, the at least one insulating material remained in the first region 101 forms dielectric layers 156, 158, which preferably include top surfaces being coplanar with the bit lines 230 within the second region 102. In one embodiment, the plugs 250 include, for example, an epitaxial material like silicon, silicon phosphorus, silicon germanium, or germanium, and the metal silicide layer 252 includes, for example, a metal silicide material like cobalt disilicide, titanium silicide, or nickel silicide, so that, the plugs 250 will therefore serve as storage node contacts of the semiconductor device 10.

Following these, a plurality of first plug openings (not shown in the drawings) is formed on the substrate 100, through another mask layer (not shown in the drawings), with each of the first plug openings penetrating through the dielectric layer 158, the etching stop layer 154 and the cover layer 138, within the first region 101, to expose the top surface of each gate structure 130 thereby. Next, the another mask layer is completely removed. Then, at least one deposition process is performed, and a barrier material layer (not shown in the drawings, including a conductive barrier material like titanium and/or titanium nitride or tantalum and/or tantalum oxide) and a metal material layer (not shown in the drawings, including a metal material like copper, aluminum, tungsten or titanium) are simultaneously formed on the substrate 100 both within the first region 101 and the second region 102. In the configuration, the barrier material layer is partially formed within the storage contact openings and the first plug openings, and partially formed outside the storage contact openings and the first plug openings, in a conformal manner, and the metal material layer is filled in the rest spaces of the storage contact openings and the first plug openings. Accordingly, at least one conductive pad 162 and landing pads 262 are formed respectively within the first region 101 and the second region 102, by performing a patterning process through another mask layer (not shown in the drawings), and the another mask layer is completely removed. Afterward, another deposition process is performed, to form a covering layer 164 within the first region 101, conformally overlaying the at least one conductive pad 162 and the dielectric layer 158, and also, to form insulating spacers 164 within the second region 102, between the adjacent ones of the landing pads 262, as shown in FIG. 3.

Further in view of FIG. 3, a supporting layer structure 200 is formed within the second region 102, and which includes, for example, at least one oxide layer and at least one nitride layer alternately stacked with each other. In one embodiment, the supporting layer structure 200 includes a first supporting material layer 202 (including, for example, silicon oxide), a second supporting material layer 204 (including, for example, silicon nitride or silicon carbonitride), a third supporting material layer 206 (including, for example, silicon oxide), and a fourth supporting material layer 208 (including, for example, silicon nitride or silicon carbonitride) sequentially stacked from bottom to top, but is not limited thereto. Then, a plurality of openings OP is formed in the supporting layer structure 200, with each of the openings OP penetrating through the fourth support material layer 208, the third support material layer 206, the second support material layer 204 and the first support material layer 202, to align with each of the landing pads 262, and the top surface of each of the landing pads 262 is exposed from each opening OP, thereby.

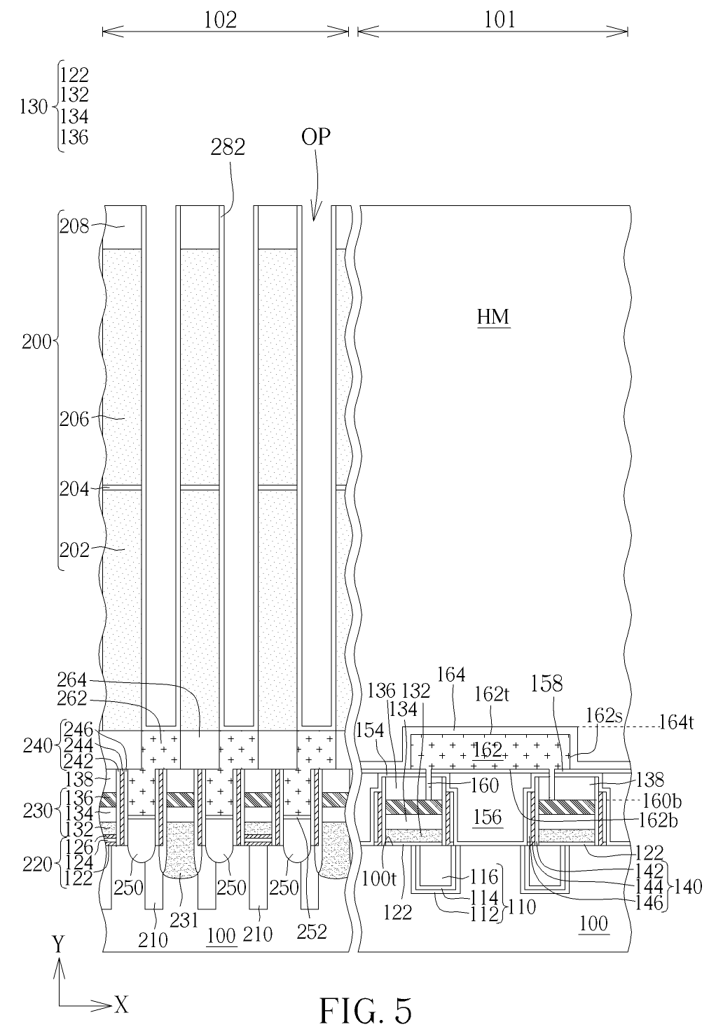

Preferably, the first support material layer 202 or the third support material layer 206, for example, being an oxide layer, may have a larger thickness, for example, about 5 times to more than 10 times greater than a thickness of the second support material layer 204 or the fourth support material layer 208, for example, being a nitride layer. Furthermore, a thickness of the nitride layer located relatively away from the substrate 100, such as the fourth support material layer 208, is preferably greater than a thickness of the nitride layer located relatively close to the substrate 100, such as the second support material layer 204, as shown in FIG. 5, but not limited thereto. Accordingly, the overall thickness of the supporting layer structure 200 may reach about 1600 angstroms to about 2000 angstroms, but is not limited thereto. It should be understood by those of ordinary skill in the art that the number of stacks of oxide and nitride layers is not limited to that illustrated in FIG. 5, but can be adjusted according to practical requirements, for example being 4 layers, 5 layers or more layers.

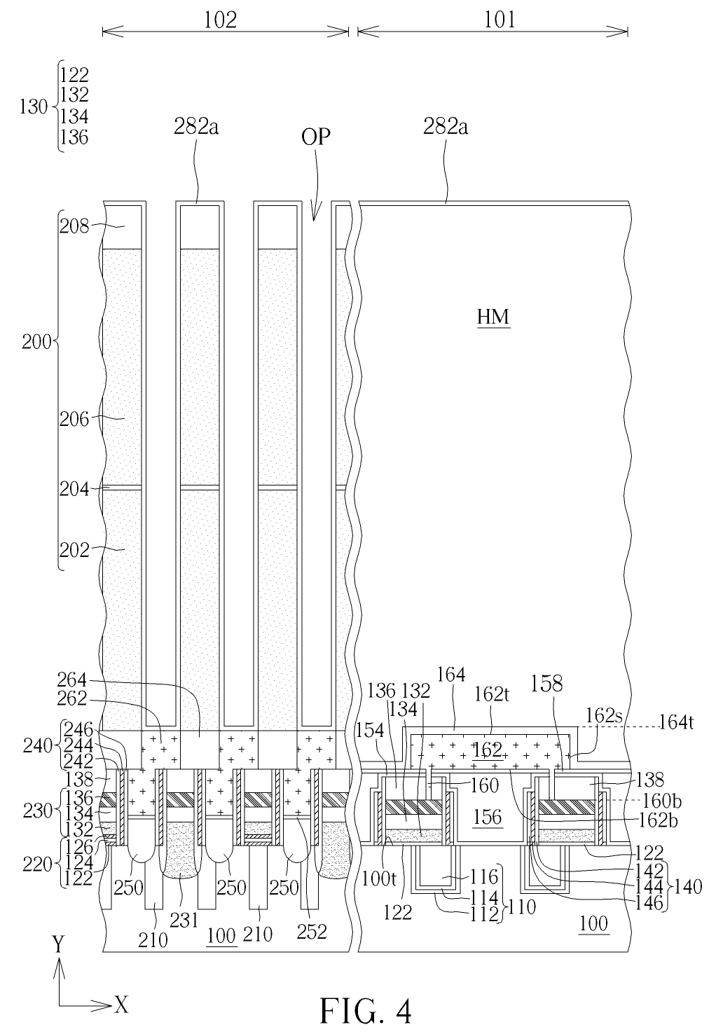

As shown in FIG. 4, a hard mask layer HM is formed on the substrate 100, within the first region 101, with the hard mask layer entirely overlaying the at least one conductive pad 162 and the gate structures 130 within the first region 101, and a deposition process is performed within the second region 102, forming a bottom electrode material layer 282s, uniformly overlaying the surfaces of each opening OP and the top surface of the supporting layer structure 200. In one embodiment, the bottom electrode material layer 282a includes, for example, a low-resistant metal material like aluminum, titanium, copper, tungsten, or a nitride thereof, and preferably for titanium nitride, but not limited thereto.

As shown in FIG. 5, an etching back process is performed, removing the bottom electrode material layer 282a (as shown in FIG. 4) overlaying the top surface of the supporting layer structure 200, and forming a plurality of bottom electrodes 282 each having a U-shaped cross-sectional structure within each opening OP. The U-shaped cross-sectional structure of each bottom electrode 282 extends vertically in the vertical direction Y, and physically contacts each landing pad 262 formed underneath.

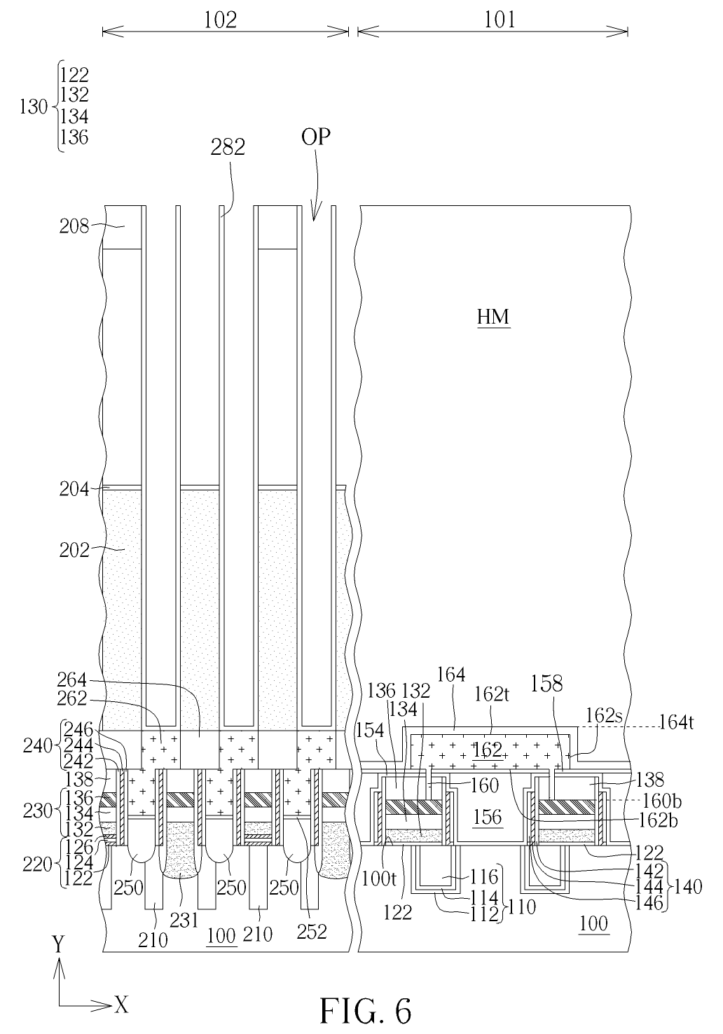

As shown in FIG. 6, at least one etching process is performed through a mask layer (not shown in the drawings), partially removing the supporting layer structure 200 as shown in FIG. 5. Precisely speaking, the mask layer includes, for example, a plurality of mask patterns (not shown in the drawings), with each mask pattern overlaying the supporting layer structure 200 and the bottom electrodes 282 in a manner of partially covering the U-shaped cross-sectional structures of two adjacent bottom electrodes 282, partially covering the supporting layer structure 200 between the two adjacent bottom electrodes 282, to partially expose the bottom electrodes 282 and the supporting layer structure 200. In the configuration, about two-thirds to one-half of any two adjacent bottom electrodes 282 are covered by the mask layer, and at least about one-third to one-half of them are exposed the mask layer, but not limited thereto. In one embodiment, the at least one etching process includes, for example, a first etching process such as a dry etching process, which is carried out by downwardly etching the supporting layer structure 200 from exposing portions, removing the third supporting material layer 206 and the fourth supporting material layer 208 exposed from the mask layer, and a second etching process such as a wet etching process, which is carried out by introducing an etchant like tetramethylammonium hydroxide (TMAH) to laterally remove the remaining third supporting material layer 206. That is, the third supporting material layer 206 is completely removed after performing the at least one etching process.

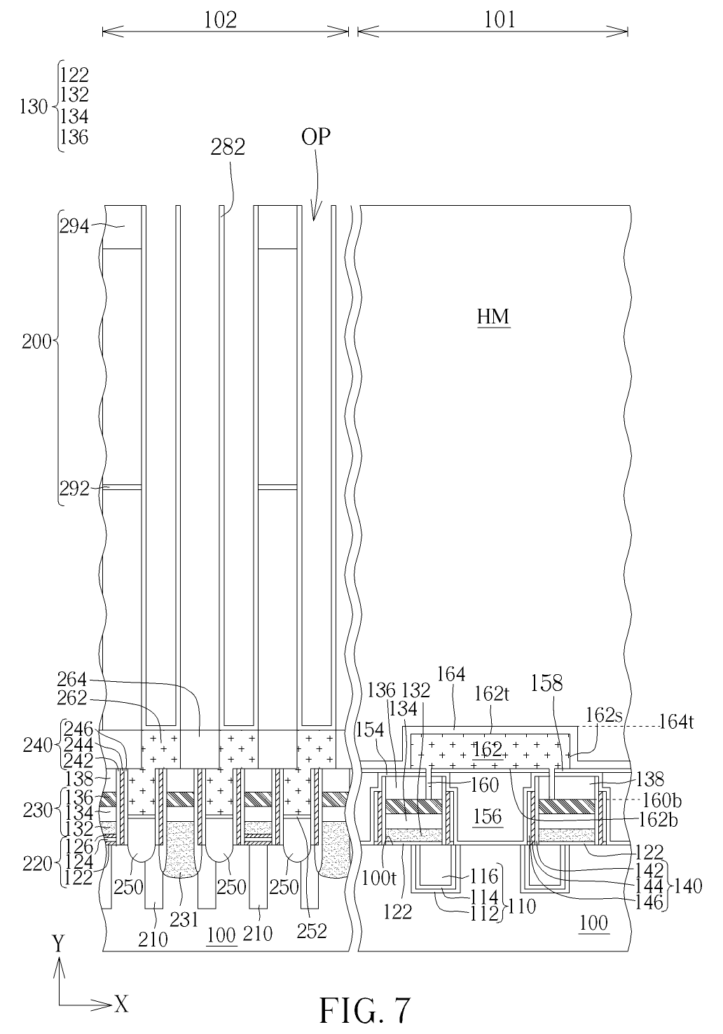

As shown in FIG. 7, a third etching process such as a dry etching process, and a fourth etching process such as a wet etching process are sequentially performed through the mask layer, with the third etching process being carried out by downwardly etching the supporting layer structure 200 from the exposed top surface of second supporting material layer 204, removing a portion of the second supporting material layer 204 and the first supporting material layer 202 underneath, and with the fourth etching process being carried out by laterally etching the remaining first supporting material layer 202 through an etchant like tetramethylammonium hydroxide. Afterward, the mask layer is completely removed. Then, the remain portion of the fourth supporting material layer 208 and the remain portion of the second supporting material layer 204 respectively form a supporting layer 294 and a first supporting layer 292 arranged from top to bottom, with the second supporting layer 294 and the first supporting layer 292 directly contacting at least one sidewall of the U-shaped cross-sectional structure of each bottom electrode 282, in the vertical direction Y. Accordingly, the second supporting layer 294 and the first supporting layer 292 together form a supporting structure 290 of the semiconductor device 10.

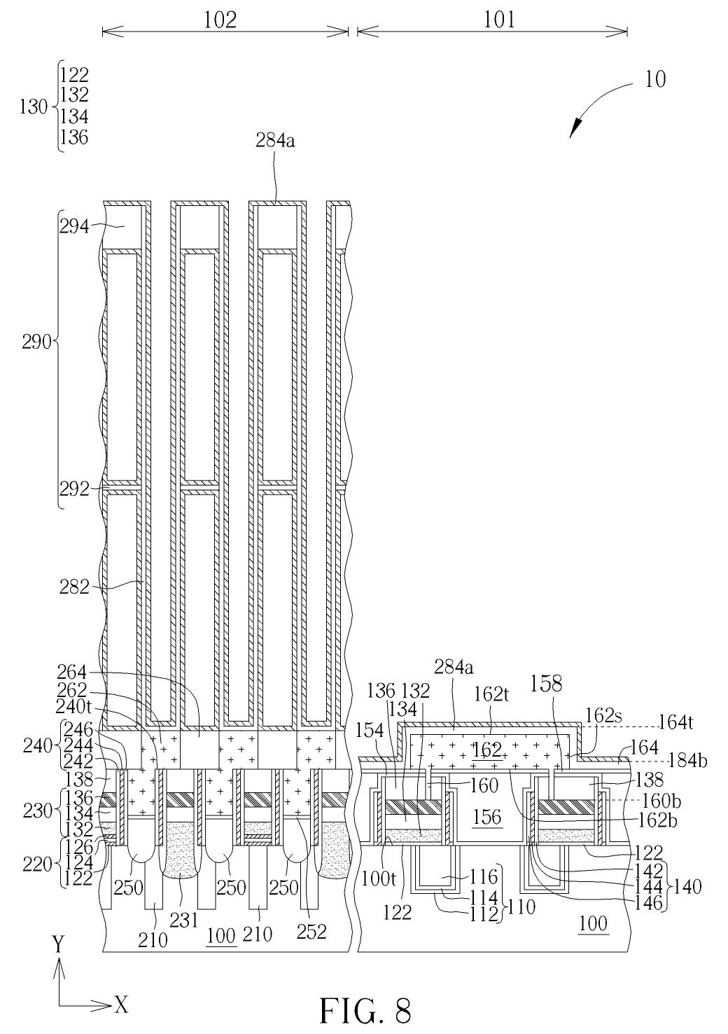

As shown in FIG. 8, the hard mask layer HM formed within the first region 101 is completely removed, and a deposition process is performed both within the first region 101 and the second region 102, to form a metal oxide material layer 284a. Precisely speaking, the metal oxide material layer 284a overlays all exposed surfaces of the supporting structure 290 and the bottom electrodes 282, with the metal oxide material layer 284a extending over the covering layer 164 and the at least one conductive pad 162 formed within the first region 101. In one embodiment, the metal oxide material layer 284a preferably includes a high dielectric constant dielectric material selected from a group consisting of hafnium oxide, hafnium silicon oxide, hafnium silicon oxynitride, zinc oxide, titanium oxide and zirconia-alumina-zirconia, but not limited thereto.

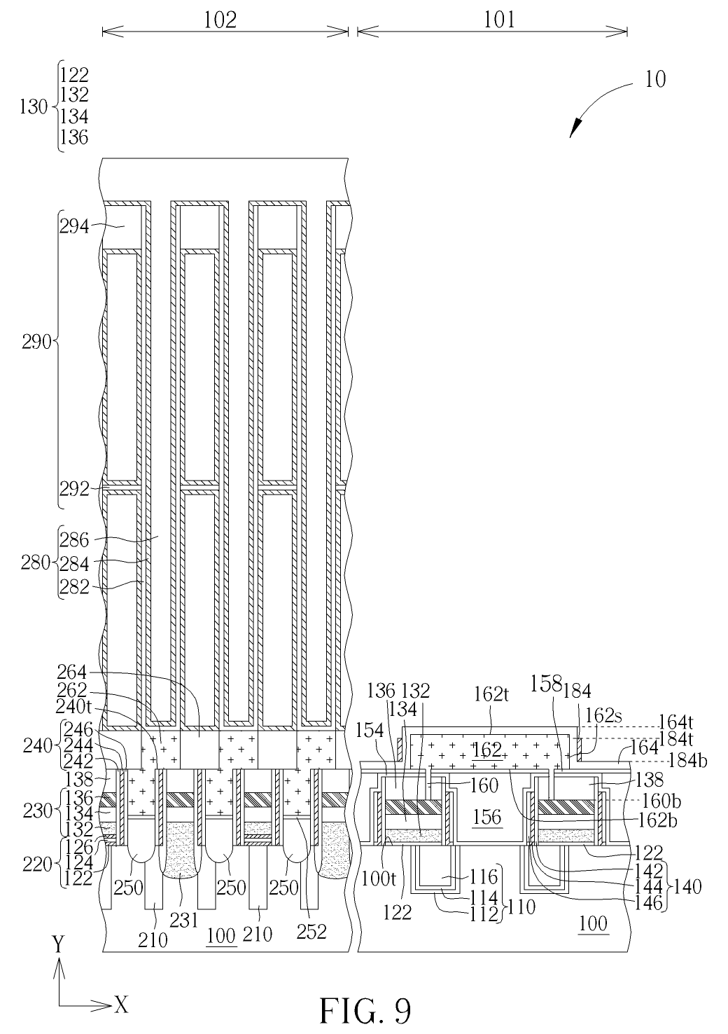

As shown in FIG. 9, an etching back process is performed through a mask layer (not shown in the drawings) completely overlaying components within the second region 102, to partially remove the metal oxide material layer 284a formed within the first region 101 as shown in FIG. 8, and to form a metal oxide layer 184 on the covering layer 164 overlaying the sidewall 162s of the at least one conductive pad 162. Meanwhile, the metal oxide material layer 284a remained in the second region 102 forms a capacitor dielectric layer 284. Next, after completely removing the mask layer, another deposition process is performed on the capacitor dielectric layer 284 in the second region 102, to form a top electrode layer 286, with the top electrode layer 286 filling in the remaining space between the adjacent bottom electrodes 282, and overlaying the capacitor dielectric layer 284. Accordingly, the bottom electrodes 282, the capacitor dielectric layer 284, and the top electrode layer 286 formed within the second region 102 together form a capacitor structure 280, and the top electrode layer 286 is further formed between the second supporting layer 294 and the first supporting layer 292, as well as between the first supporting layer 292 and the insulating spacers 264, thereby increasing contact area and raising capacitance. In one embodiment, the top electrode layer 286 includes a low-resistance metal material such as aluminum, titanium, copper, tungsten, or a nitride thereof, and preferably includes a composite structure of titanium nitride and silicon germanium, but not limited thereto. Through these performances, the fabrication of the capacitor structure 280 is accomplished. Following these, second plugs 166 which are electrically connected to the at least one conductive pad 162, and an insulating layer 170 entirely overlying the second plugs 166 and the at least one conductive pad 162 are then formed within the first region 101, thereby accomplishing the fabrication of the semiconductor device as shown in FIG. 1.

With these performances, each bottom electrode 282 in the capacitor structure 280, and the capacitor dielectric layer 284 and the top electrode layer 286 formed above each bottom electrode 282 together form a vertically extending capacitor, which can serve as a storage node of the semiconductor device 10 for electrically connected with a transistor component (not shown in the drawing) in the substrate 100 through the storage node pads (namely the landing pads 262) and the storage node plugs (namely the plugs 250). That is, the capacitor structure 280 and the storage node plugs formed over the substrate 100 will therefore achieve better electrical connection therebetween. In this way, each capacitor and the transistor component are together form the smallest unit in a memory array for accepting signals from the bit lines 230 and word lines (not shown in the drawings), and the semiconductor device 10 in the present embodiment can form a dynamic random access memory (DRAM) device, to gain improved performance and functions.

According to the method of fabricating the semiconductor device 10 of the present embodiment, the metal oxide layer 184 is formed on the covering layer 164 overlaying the sidewall 162s of the at least one conductive pad 162, as the capacitor dielectric layer 284 of the capacitor structure 280 is formed, such that, the topmost point 184t of the metal oxide layer 184 is lower than the topmost point 164t of the covering layer 164, and the top surface 162t of the at least one conductive pad 162, and the lowest point 184b of the metal oxide layer 184 is higher than the lowest point 160b of the first plug 160, and the bottom surface 162b of the at least one conductive pad 162. Through forming the metal oxide layer 184 in the semiconductor device, the structural defects possibly occurred on components within the peripheral region of the semiconductor device 10 are dramatically improved, without additionally increasing the entire height of components within the peripheral region of the semiconductor device 10, and the short circuit issues between the at least one conductive pad 162 and metal interconnections adjacent thereto will be successfully avoided thereby. In this way, the semiconductor device 10 formed according to the fabricating method of present embodiment is allowable to gain better structural reliability and functions.

It could be easily understood by those of ordinary skill in the art that the semiconductor device according to the present invention may have alternative forms not limited to the above, for meeting practical requirements of products. Hereinafter, other embodiments or variations of the semiconductor device according to the present invention will be further described. For simplification, the following descriptions are mainly focused on the differences between embodiments, and will not repeat the similarities. In addition, the same components in various embodiments of the present invention are labeled with the same reference numerals, so as to facilitate mutual comparison among various embodiments.

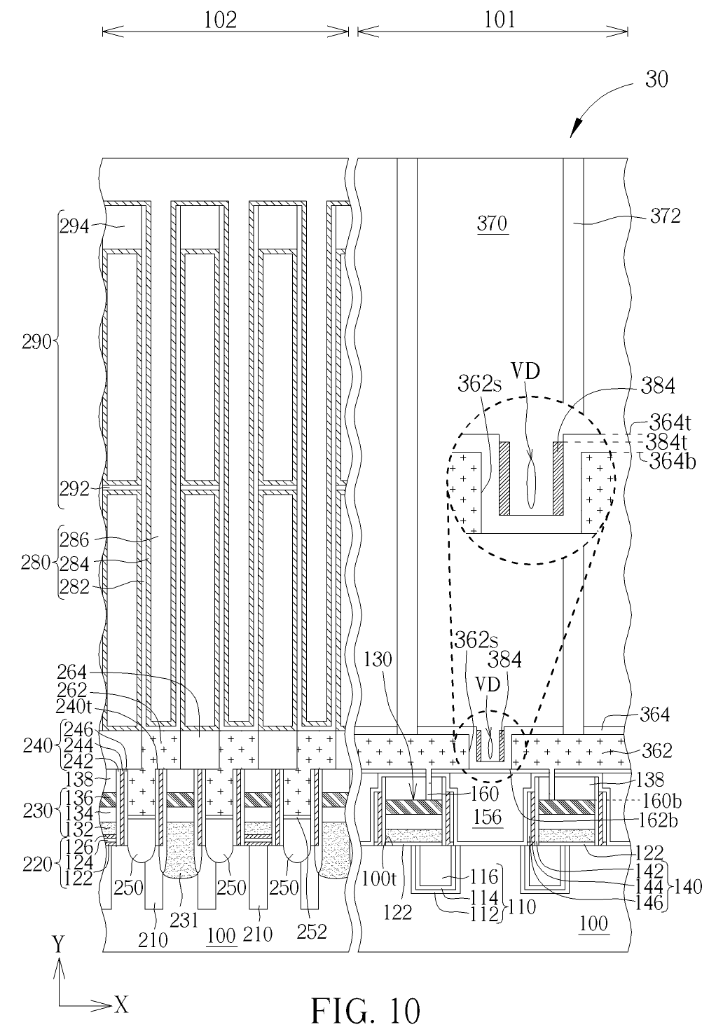

Please refer to FIG. 10, which schematically illustrates a semiconductor device 30 according to a second embodiment of the present invention. The structure and the steps of forming the semiconductor device 30 in the present embodiment are basically the same as those of the semiconductor device 10 in the first embodiment, with all similarities being not redundantly described hereinafter. The main difference between the semiconductor device 30 of the present embodiment and the semiconductor device 10 of the aforementioned embodiment is that a metal oxide layer 384 of the present embodiment is disposed between two gate structures 130 in the vertical direction Y.

Precisely speaking, the semiconductor device 30 includes two conductive pads 362, respectively disposed above the two gate structures 130, with the conductive pads 362 physically contacting two first plugs 160 and two second plugs 372, respectively. It is noted that one sidewall 362s of each conductive pad 362 is disposed between the two gate structures 130, and the metal oxide layer 384 is disposed on a covering layer 384 overlaying the sidewall 362s of each conductive pad 362, right between the two gate structures 130, as shown in FIG. 10. Preferably, the top surface 384t of the metal oxide layer 384 is higher than the bottom surface 364b of the covering layer 364, and is lower than the top surface 364t of the covering layer 364. In other words, the top surface 384t of the metal oxide layer 384 is located between the bottom surface and the top surface of the covering layer 364, without increasing the height component within the peripheral area. In one embodiment, the semiconductor device 30 may optionally include an air gap VD disposed in the insulating layer 370, with the air gap VD being disposed between the metal oxide layers 384 disposed on the sidewalls 362s of the two conductive pads 362, for effectively prevent from short circuit issue by further isolating unnecessary contacts between the conductive pads 362 and the components adjacent thereto.

Through these arrangements, the metal oxide layer 384 of the present embodiment will also dramatically improve the structural defect possibly occurred on components within the periphery region of the semiconductor device 30, without additionally increasing the entire height of components within the periphery region, so that, the short circuit issues between the conductive pads 362 and metal interconnections adjacent thereto will be successfully avoided thereby. In this way, the semiconductor device 30 in the present embodiment is allowable to gain better structural reliability and functions, under simplified fabricating process.

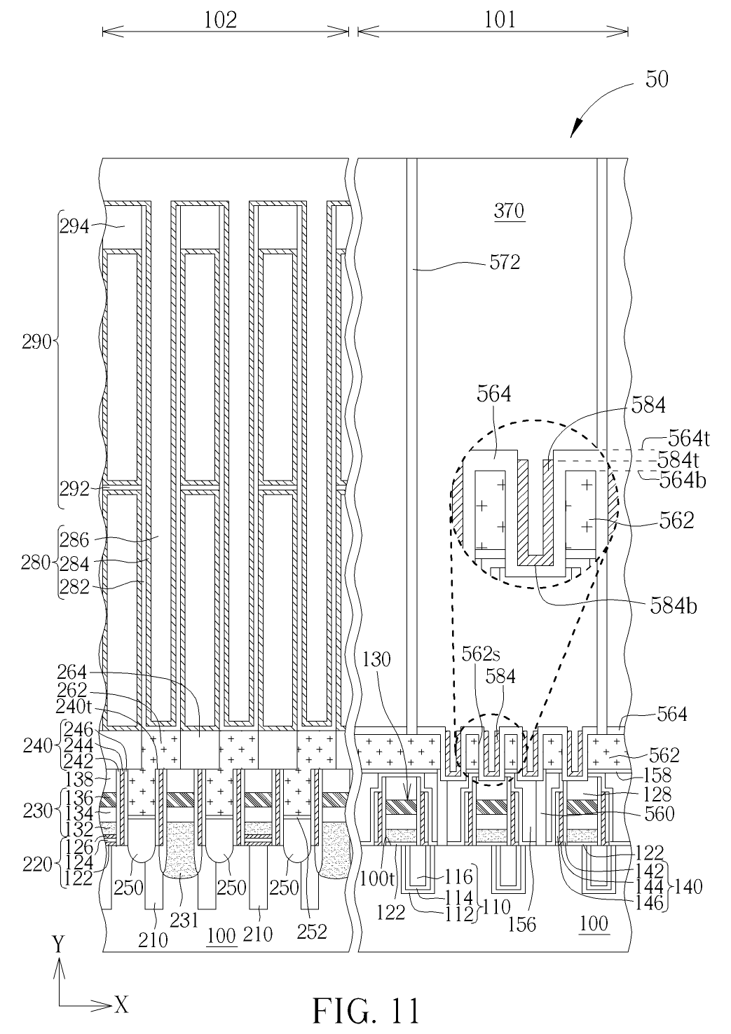

Please refer to FIG. 11, which schematically illustrates a semiconductor device 50 according to a third embodiment of the present invention. The structure and the steps of forming the semiconductor device 50 in the present embodiment are basically the same as those of the semiconductor device 10 in the first embodiment, with all similarities being not redundantly described hereinafter. The main difference between the semiconductor device 50 of the present embodiment and the semiconductor device 10 of the aforementioned embodiment is that metal oxide layer 584 of the present embodiment is simultaneously disposed above the gate structures 130 and between the adjacent gate structures 130.

Precisely speaking, the semiconductor device 50 includes a plurality of conductive pads 562, respectively disposed above the gate structures 130, and above the dielectric layer 156 disposed between the gate structures 130, with a portion of the conductive pads 562 physically contacting two plugs 572, and two first plugs 560 which are electrically connected to a corresponding doped region in the substrate 100, respectively. It is noted that, the metal oxide layers 584 of the preset embodiment are each disposed between the adjacent ones of the conductive pads 562, on a covering layer 564 disposed on the sidewall 562s of each conductive pad 562, with at least one of the metal oxide layers 584 being disposed right above a corresponding one of the gate structures 130, and with at least one of the metal oxide layers 584 being disposed between the adjacent gate structures 130, above a corresponding one of the first plugs 560. Furthermore, the capping layer 564 of the present embodiment partially extends into the dielectric layers 156, 158, to physically contact the first plugs 560 or the capping layer 138 disposed over at least one gate structure 130. Accordingly, the top surface 584t of the metal oxide layer 584 is preferably between the bottom surface 564b and the top surface 564t of the covering layer 564, and the bottom surface 584b of the metal oxide layer 584 is lower than the bottom surface of the contact pad 562, without additionally increasing the height of components within the peripheral area. It is also noted that, due to the limited space between the adjacent conductive pads 562, the metal oxide material layer overlaying the bottom surface of the limited space will not be removed during performing the etching back process as shown in FIG. 9. Accordingly, each of the metal oxide layers 584 will therefore obtain a U-shaped cross-sectional structure as shown in FIG. 11, but not limited thereto.

Through these arrangements, the metal oxide layer 584 of the present embodiment will also dramatically improve the structural defect possibly occurred on components within the periphery region of the semiconductor device 50, without additionally increasing the entire height of components within the periphery region, so that, the short circuit issues between the conductive pads 562 and metal interconnections adjacent thereto will be successfully avoided thereby. In this way, the semiconductor device 50 in the present embodiment is allowable to gain better structural reliability and functions, under simplified fabricating process.

Overall speaking, processes of forming components in various regions are integrated with each other in the present invention, with a metal oxide layer being additionally formed above a gate structure within a peripheral region under a simplified process, so that, an unnecessary contact between a conductive pad disposed above the gate structure, and metal interconnection adjacent to the conductive pad will be effective avoided, without leading to any increase of component heights within the peripheral region. The structural defects usually occurred at the peripheral region of semiconductor device will be effectively improved, so as to gain better structural reliability and functions.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first plug, disposed on the substrate;
a conductive pad, disposed on the first plug and physically contacting the first plug;
a covering layer, comprising a first portion disposed on a top surface of the conductive pad and a second portion disposed on a sidewall of the conductive pad; and
a metal oxide layer, disposed on the second portion of the covering layer, wherein a topmost point of the metal oxide layer is lower than a topmost point of the covering layer, and a lowest point of the metal oxide layer is higher than a lowest point of the first plug.

2. The semiconductor device according to claim 1, further comprising:
a first shallow trench isolation, disposed in the substrate;
a first gate structure, disposed on the shallow trench isolation, wherein the first plug physically contacts the first gate structure; and
a second plug, disposed on the conductive pad and electrically connected to the conductive pad.

3. The semiconductor device according to claim 2, wherein the first gate structure comprises a gate dielectric layer, a semiconductor layer, a barrier layer and a metal layer disposed in sequence, and the first plug physically contacts the metal layer of the first gate structure.

4. The semiconductor device according to claim 1, wherein the conductive pad and the first plug are monolithic.

5. The semiconductor device according to claim 2, further comprising:
a spacer structure, disposed on a sidewall of the first gate structure and partially disposed on the first shallow trench isolation; and
an etching stop layer, disposed on the substrate and overlaying the first gate structure and the spacer structure, wherein a lowest point of the etching stop layer is lower than a topmost surface of the substrate.

6. The semiconductor device according to claim 5, wherein the first shallow trench isolation comprises a first insulating layer, a second insulating layer and a third insulating layer being lower than the topmost surface of the substrate, wherein the second insulating layer is higher than the first insulating layer, and the etching stop layer physically contacts a sidewall of the second insulating layer and a top surface of the first insulating layer.

7. The semiconductor device according to claim 6, wherein the spacer structure comprises a first spacer, a second spacer and a third spacer disposed in sequence on the sidewall of the first gate structure, wherein the second spacer physically contacts the sidewall and a top surface of the second insulating layer and a top surface of the third insulating layer, and a bottom surface of the third spacer is higher than bottom surfaces of the first spacer and the second spacer.

8. The semiconductor device according to claim 2, wherein the metal oxide layer is disposed above the first gate structure.

9. The semiconductor device according to claim 2, further comprising:
a second shallow trench isolation, disposed in the substrate; and
a second gate structures, disposed on the second shallow trench isolation.

10. The semiconductor device according to claim 9, wherein two opposite sidewalls of the conductive pad are respectively disposed on the first gate structure and the second gate structure, and the metal oxide layer is disposed on the covering layer disposed on the two opposite sidewalls of the conductive pad.

11. The semiconductor device according to claim 9, wherein the sidewall of the conductive pad is disposed between the first gate structure and the second gate structure, and the metal oxide layer is disposed on the covering layer disposed on the sidewall of the conductive pad.

12. The semiconductor device according to claim 9, further comprising:
another conductive pad, disposed on a third plug and physically contacting the third plug, wherein the covering layer disposed on a sidewall and a top surface of the another conductive pad;
another metal oxide layer, disposed on the covering layer disposed on the sidewall of the another conductive pad;
an insulating layer disposed between the metal oxide layer and the another metal oxide layer; and
an air gap disposed in the insulating layer, between the metal oxide layer and the another metal oxide layer.

13. The semiconductor device according to claim 9, further comprising:
another conductive pad, disposed on the first gate structure, wherein the covering layer disposed on a sidewall and a top surface of the another conductive pad, and the metal oxide layer comprises an U-shaped structure simultaneously disposed on the covering layer disposed on the sidewall of the conductive pad and the sidewall of the another conductive pad; and
an insulating layer disposed on the U-shaped structure of the metal oxide layer.

14. A fabricating method of a semiconductor device, comprising:
providing a substrate;
forming a first plug on the substrate;
forming a conductive pad on the first plug, the conductive pad in physical contact with the first plug;
forming a covering layer on the conductive pad, comprising a first portion on a top surface of the conductive pad and a second portion on a sidewall of the conductive pad; and
forming a metal oxide layer on the second portion of the covering layer, wherein a topmost point of the metal oxide layer is lower than a topmost point of the covering layer, and a lowest point of the metal oxide layer is higher than a lowest point of the first plug.

15. The fabricating method of the semiconductor device according to claim 14, further comprising:
forming a plurality of bit lines on the substrate;
forming a plurality of landing pads on the substrate, being alternately arranged with the plurality of bit lines; and
forming a capacitor structure on the landing pads, the capacitor structure comprising a plurality of bottom electrodes, a capacitor dielectric layer and a top electrode, wherein the capacitor dielectric layer and the metal oxide layer comprise a same dielectric material.

16. The fabricating method of the semiconductor device according to claim 15, forming the metal oxide layer further comprising:
forming a metal oxide material layer, entirely overlaying the covering layer and the conductive pad; and
partially removing the metal oxide material layer, simultaneously forming the metal oxide layer and the capacitor dielectric layer.

17. The fabricating method of the semiconductor device according to claim 16, further comprising:
forming a first shallow trench isolation in the substrate; and
forming a first gate structure on the first shallow trench isolation, wherein the first plug physically contacts the first gate structure, and the metal oxide layer is formed right above the first gate structure.

18. The fabricating method of the semiconductor device according to claim 17, further comprising:
forming a second shallow trench isolation;
forming a second gate structure on the second shallow trench isolation; and
forming a second plug, physically in contact with the second gate structure, wherein the sidewall of the conductive pad is formed between the first gate structure and the second gate structure, and the metal oxide layer is formed on the second portion of the covering layer .

19. The fabricating method of the semiconductor device according to claim 18, further comprising:
forming another conductive pad on the second plug and physically contacting the second plug, wherein the covering layer further covers a sidewall and a top surface of the another conductive pad;
forming another metal oxide layer on the covering layer covering the sidewall of the another conductive pad;
forming an insulating layer between the metal oxide layer and the another metal oxide layer; and
forming an air gap in the insulating layer, between the metal oxide layer and the another metal oxide layer.

20. The fabricating method of the semiconductor device according to claim 16, after forming the bottom electrode, further comprising:
forming the metal oxide material layer.
